(19) United States
(12) Patent Application Publication
(10) Pub. No.: US 2024/0339742 A1
(43) Pub. Date: Oct. 10, 2024

(54) COMPACT BALUN STRUCTURE FOR BROADBAND TIME-DOMAIN APPLICATIONS

(71) Applicant: Tektronix, Inc., Beaverton, OR (US)

(72) Inventor: Daniel G. Knierim, Beaverton, OR (US)

(21) Appl. No.: 18/613,687

(22) Filed: Mar. 22, 2024

Related U.S. Application Data
(60) Provisional application No. 63/458,069, filed on Apr. 7, 2023.

(51) Int. Cl. H01P 1/00; G01R 27/02; H01P 3/08

(52) U.S. Cl. CPC H01P 1/00; G01R 27/02; H01P 3/08

(57) ABSTRACT

A broadband balun structure has a single-ended port, a balanced port, a first transmission line connected between the single-ended port and one side of the balanced port, and a second transmission line connected to the other side of the balanced port, the first transmission line positioned to allow coupling of a first portion of the first transmission line simultaneously to both a second portion of the first transmission line and a portion of the second transmission line. A broadband balun structure includes a 180° hybrid using coupled-line structures, and a phase-shift network using coupled-line structures, the coupled-line structures positioned to couple at least one line section simultaneously to two other line sections. A test and measurement system and a test and measurement instrument, and at least one balun structure.

### CROSS-REFERENCE TO RELATED APPLICATIONS

This disclosure is a non-provisional of and claims benefit from U.S. Provisional Application No. 63/458,069, titled “COMPACT BALUN STRUCTURE FOR BROADBAND TIME-DOMAIN APPLICATIONS,” filed on Apr. 7, 2023, the disclosure of which is incorporated herein by reference in its entirety.

### TECHNICAL FIELD

This disclosure relates to test and measurement instruments, and more particularly to a compact balun structure for use in test and measurement applications.

### BACKGROUND

U.S. Pat. No. 8,611,436, issued Dec. 17, 2013, hereinafter “the '436 patent,” the contents of which are hereby incorporated by reference into this disclosure, describes broadband balun structures optimized for time-domain applications. The term “balun” as used here means a device that connects between balanced, or differential, and unbalanced. or single-ended, sections of circuitry. The term “broadband” as used here means covering from DC (or a very low frequency) up to the rated bandwidth of the balun. Generally, the rated bandwidth is the frequency at which the delay and coupled sections of the transmission line in a 180° hybrid, discussed below, are quarter-wavelength. At higher frequencies, above the quarter-wavelength frequency, the coupling becomes less effective, resulting in less benefit from the balun. The balun has amplitude and phase response designed to cancel interconnect loss so as to provide a clean system step response shape. Such broadband baluns are useful, for example, on the output of a differential probe amplifier driving a single-ended cable to a test and measurement instrument, such as an oscilloscope (“scope”), and/or for a single-ended scope input driving a differential input amplifier.

FIG. 1 illustrates an example balun structure, where thick lines such as 10 represent intentional delay lines, closely-spaced thick lines represent coupled-pair delay lines, such as 12 and 14, and thin lines such as 16 represent interconnects. The structure needs the thin lines to physically separate the intentional delays to avoid unwanted coupling. The thin lines will induce additional delay, but only where that delay is not inherent to the operation of the balun.

FIG. 2 illustrates a version of the same basic structure with a simplified phase-shift network shown by lines 18 and 20.

### BRIEF DESCRIPTION OF THE DRAWINGS

FIG. 1 shows an example of a balun structure.

FIG. 2 shows an example of a balun structure with a simplified phase-shift network.

FIG. 3 shows an embodiment of test and measurement instrument connected to a device under test (DUT) using one or more balun structures.

FIG. 4 shows an embodiment of a balun structure.

FIG. 5 shows an alternative embodiment of a balun structure.

FIG. 6 shows an implementation of a balun structure on a printed circuit board (PCB).

FIG. 7 shows an embodiment of a balun structure in different layers of a PCB.

FIG. 8 shows a resulting time-domain step response of an output of an embodiment of a balun structure.

### DETAILED DESCRIPTION

A test and measurement system may employ one or more balun structures implemented into a probe 32 and/or a test and measurement device 30 as part of a test and measurement system, as shown in FIG. 3. For example, the balanced port of balun 33 may connect to a differential amplifier output within probe 32 of the test and measurement system, and the single-ended port connects to cable 34 between the probe and the test and measurement instrument. In another example, the single-ended port of another balun 36 may connect to the cable 34 and the balanced port of balun 36 connects to a differential input amplifier 38 on the input of the test and measurement device 30. The system may use one balun in either of the above examples or use them together as shown.

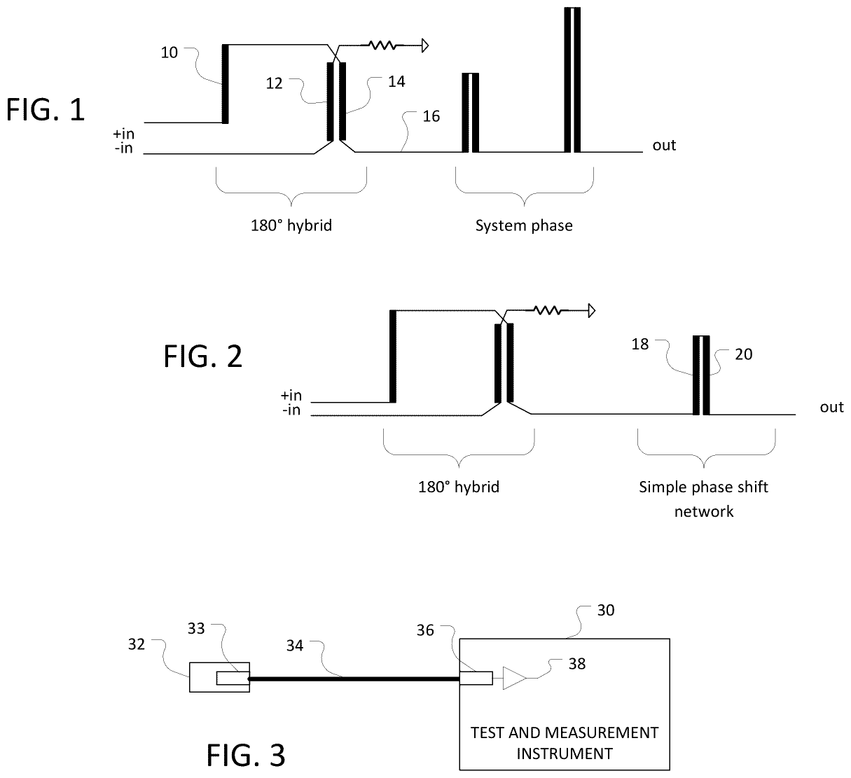

According to embodiments of this disclosure, either of the structures shown in FIGS. 1 and 2 as well as other constructions disclosed in the '436 patent, may be made more compact through the use of coupled-triple delay lines. Generally, the embodiments involve a broadband balun having a single-ended port, a balanced port having first and second sides, a first transmission line connected between the single-ended port and the first side of the balanced port, and a second transmission line connected to the second side of the balanced port. The first transmission line is positioned to couple a first portion of the first transmission line simultaneously to both a second portion of the first transmission line and a portion of the second transmission line.

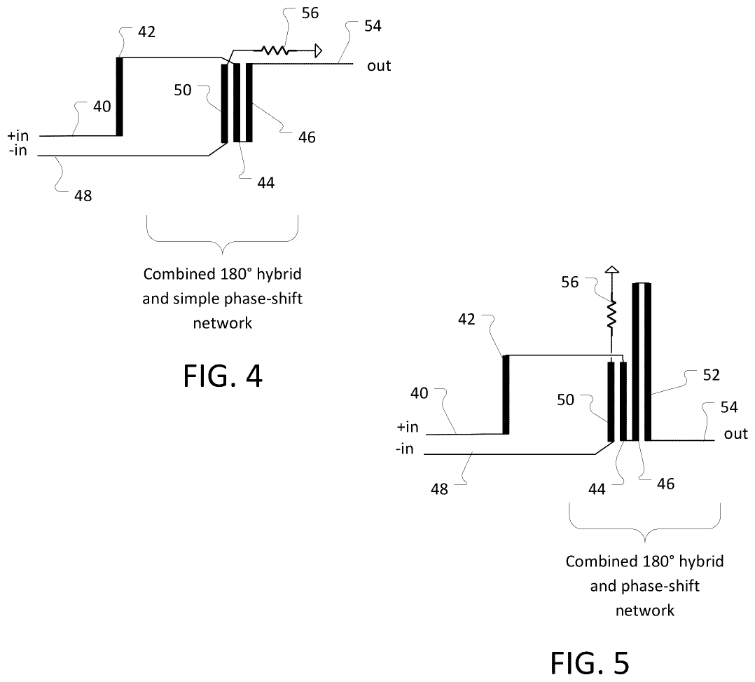

The embodiments may have two schematically adjacent coupled-pair sections combined to share a common delay segment, coupled on one side to implement one coupled-pair, and coupled on the other side to implement the other coupled-pair. “Schematically adjacent” as used here means directly connected with a thin line in the schematic without any intervening thick lines. These line sections may be coupled by placing them adjacent on a planar surface, such as on a same surface of a layer of a substrate, or in adjacent layers of a substrate. FIG. 4 shows a simplified structure resulting from application of this approach to the design of the balun in FIG. 2.

In FIG. 4, transmission line 40 connects between one side of the balanced port and the single-ended port 54, and has a first delay portion 42, and a coupled-pair comprised of portions 44 and 46. The second transmission line 48 connects to the other side of the balanced port and has a coupled-pair section comprised of portions 50 and 44, and connects to a resistor 56 as a termination component. Portion 44 comprises the common delay segment that couples to both sections 46 and 50 simultaneously, forming a “coupled-triple.” The balun forms a combined 180° hybrid and simple phase shift network.

The embodiment of FIG. 4 uses less layout spacing, making it more compact, and has lower loss. The lower loss results from having one less intentional delay segment and less interconnect length. The same approach applied to the original structure of FIG. 1 yields the structure illustrated in FIG. 5.

In FIG. 5, transmission line 40 has delay portion 42 and two coupled pairs. A first coupled-pair comprises portions 44 and 46, and a second coupled-pair comprised of portions 46 and 52. A third coupled-pair comprises portion 50 of transmission line 48 that couples with portion 44. Transmission line 48 has a termination component in the form of a resistor 56. This embodiment saves even more space and removes two intentional delay segments from the original layout.

One can apply this approach to other balun structures, such as those disclosed in the '436 patent, to make balun structures more physically compact through the use of these types of coupled-triple delay lines, according to other embodiments of this disclosure.

For typical stripline implementations of the balun structures, the coupled-pair delay segments will be narrower than the uncoupled delay segments in order to match the geometric mean of the even-mode (Ze) and odd-mode (Zo) impedances to the system's single-ended impedance (Z0). This can be viewed as reducing the width of the coupled line on the coupled side in order to compensate for the proximity of the other line of the pair. Accordingly, in the compact structures of embodiments of this disclosure, lines that are coupled on both sides need this width reduction applied on both sides and will be even narrower than lines coupled on only one side, which are in turn narrower than uncoupled lines. This simplistic equal-narrowing-per-coupled-edge approach works quite well in estimating coupled-triple line widths for this compact design approach, but 2-D or 3-D electromagnetic (EM) field solvers can be used to fine-tune the results to achieve the desired impedances in order to minimize reflection coefficients and precursors in the step response.

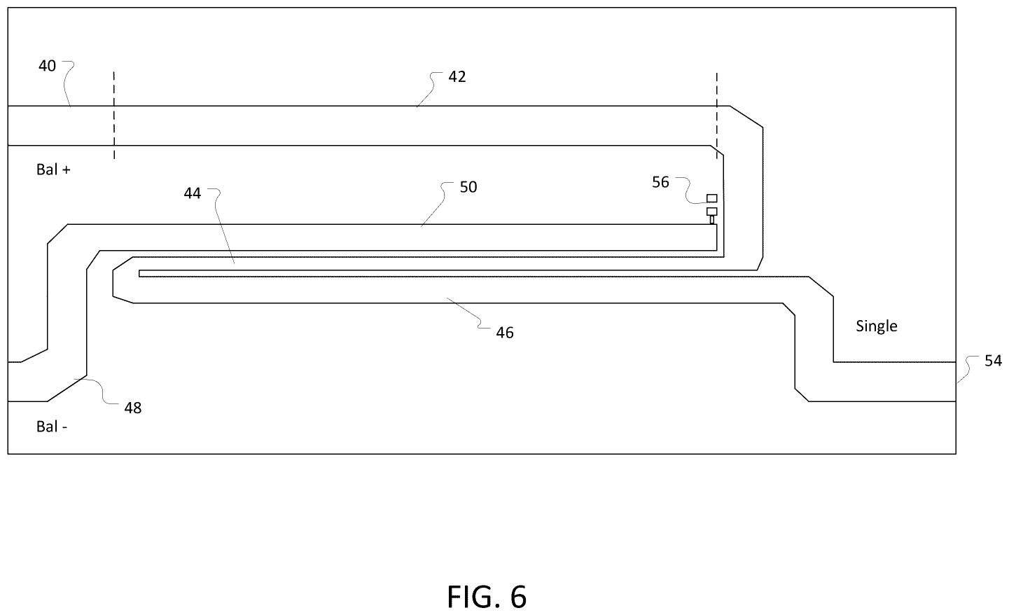

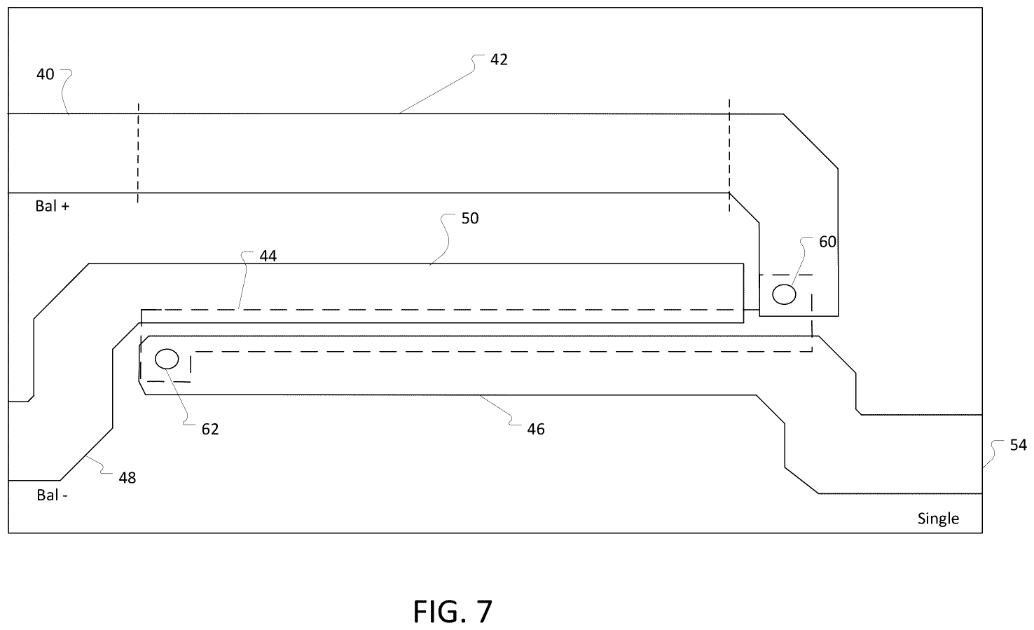

These balun structures according to embodiments of the disclosure may be implemented in various technologies, including PCBs, package substrates, and ASICs. FIG. 6 shows an example implementation with a transmission line 40 between a first side of the balanced port and the single-ended port 54, with portion 42 between the dottted lines as a delay segment prior to the coupled pair. The segment 44 of transmission line 40 that lies adjacent to the segment 50 of the transmission line 48 forms the shared segment between the coupled-pair 50 and 44 and the coupled-pair 44 and 46. Transmission line 48 connects to the other side of the balanced port and terminates with termination component 56.

In an alternative embodiment, as mentioned above, the coupled transmission lines or portions of them, may reside on different layers of a substrate, such as a PCB. As shown in FIG. 7, one or more transmission line segments, shown with dashed lines, may lie in a layer of the substrate above or below the layer on which other transmission line segments lie. The embodiments of FIG. 6 achieve coupling by broadside coupling between the parallel lines. In the embodiments using different layers on a substrate, the coupling results from the at least partial overlap of the patterns on the respective layers, referred to here as parallel-plate coupling. In the embodiment shown in FIG. 7, segment 44 would reside on a different layer than segments 50 and 46. As segments 42, 44, and 46 are part of the same transmission line, vias, such as 60 and 62 would connect 42 to 44 and 44 to 46. In another possible embodiment, the transmission line segment 50 may reside on a third layer different from the segments 44 and 46 to minimize the coupling between 46 and 50. FIG. 7 does not show the termination component to allow a clearer view of the segment in the other layer, but one may be present. The termination component is not an inherent part of the balun.

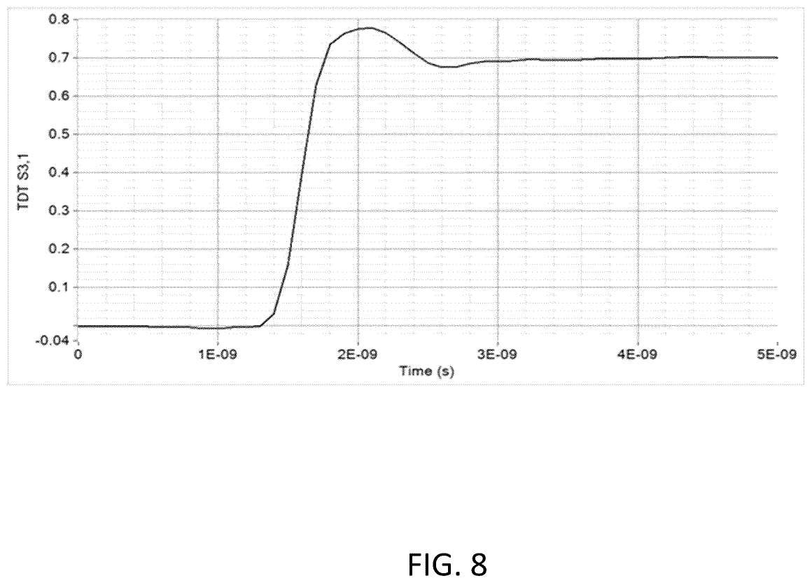

The compact simplified structure shown in FIG. 6 was built on a PCB, measured on a VNA, and converted to an equivalent time-domain step response through an IFT (Inverse Fourier Transform). FIG. 8 shows the results.

The results show a roughly 2 dB boost in gain at the design frequency of 700 MHz, where the delay segments represent a quarter-wavelength. The phase response is such that the step response is overshot after the step, ideal for compensating the post-step settling errors (aka “dribble-up”) common of interconnect loss. The subtle precursor to the step is due to imperfect impedance matching in the coupled-triple section of the structure. Again, 2-D or 3-D EM field solvers can be used to fine-tune the line widths and spacings to minimize this precursor.

The baluns of the embodiments have much more compact structures, making them easier to implement in smaller spaces. The compactness of this new approach makes implementing baluns practical in such wide-ranging applications from a PCB at 1 GHz (λ/4≈1.5 inch) to an ASIC at 60 GHz (λ/4≈630 μ).

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a broadband balun structure, comprising: a single-ended port; a balanced port; a first transmission line connected between the single-ended port and one side of the balanced port; and a second transmission line connected to the other side of the balanced port, the first transmission line positioned to allow coupling of a first portion of the first transmission line simultaneously to both a second portion of the first transmission line and a portion of the second transmission line.

Example 2 is the broadband balun structure of Example 1, wherein the second transmission line also connects to a termination component.

Example 3 is the broadband balun structure of either of Examples 1 or 2, wherein the second portion of the first transmission line is positioned to allow coupling simultaneously to a third portion of the first transmission line.

Example 4 is the broadband balun structure of any of Examples 1 through 3, wherein the transmission lines comprise one of stripline or microstrip.

Example 5 is the broadband balun structure of Example 4, wherein the coupling comprises broadside coupling of parallel line portions.

Example 6 is the broadband balun structure of Example 4, wherein the coupling comprises parallel-plate coupling of at least partially overlapped line portions on different layers.

Example 7 is the broadband balun structure of Example 4, wherein coupled portions of the first and second transmission lines are narrower than uncoupled portions of the first and second transmission lines.

Example 8 is the broadband balun structure of Example 4, wherein coupled portions of the first and second transmission lines positioned to couple simultaneously to two other line portions are narrower than portions coupled to only one other line portion.

Example 9 is a broadband balun structure, comprising: a 180° hybrid using coupled-line structures; and a phase-shift network using coupled-line structures, the coupled-line structures positioned to couple at least one line section simultaneously to two other line sections.

Example 10 is the broadband balun structure of Example 9, wherein the at least one line section simultaneously coupled to two other line sections is part of the 180° hybrid and the phase-shift network.

Example 11 is the broadband balun structure of either or Examples 9 or 10, wherein the coupled-line structures are positioned to couple at least a second line section simultaneously to two other line sections.

Example 12 is the broadband balun structure of any of Examples 9 through 11, wherein the coupled-line structures comprise one of stripline or microstrip.

Example 13 is the broadband balun structure of Example 12, wherein the coupled-line structures comprise parallel lines coupled by broadside coupling of the parallel lines.

Example 14 is the broadband balun structure of Example 12, wherein the coupled-line structures comprise lines on different layers of a substrate coupled by parallel-plate coupling of at least partially overlapped lines on different layers.

Example 15 is the broadband balun structure of Example 12, wherein line sections coupled to other line sections are narrower than uncoupled line sections.

Example 16 is the broadband balun structure of Example 12, wherein line sections coupled simultaneously to two other line sections are narrower than sections coupled to only one other line section.

Example 17 is a test and measurement system, comprising: a test and measurement instrument; and at least one balun structure comprising: a single-ended port; a balanced port having first and second sides; a first transmission line connected between the single-ended port and the first side of the balanced port; and a second transmission line connected to the second side of the balanced port, the first transmission positioned to couple a first portion of the first transmission line simultaneously to both the second portion of the first transmission line and a portion of the second transmission line.

Example 18 is the test and measurement system of Example 17, further comprising a probe connected to the test and measurement instrument by a cable, wherein the at least one balun structure comprises one balun structure having the balanced port connected to the probe and the single-ended port connected to the cable.

Example 19 is the test and measurement system of either of Examples 17 or 18, the test and measurement instrument further comprising an input amplifier, and the at least one balun structure comprises one balun structure having the singled-ended port connected to an input connector and a balanced port connected to the input amplifier.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A broadband balun structure, comprising:
a single-ended port;
a balanced port;
a first transmission line connected between the single-ended port and one side of the balanced port; and
a second transmission line connected to the other side of the balanced port,
the first transmission line positioned to allow coupling of a first portion of the first transmission line simultaneously to both a second portion of the first transmission line and a portion of the second transmission line.

2. The broadband balun structure as claimed in claim 1, wherein the second transmission line also connects to a termination component.

3. The broadband balun structure as claimed in claim 1, wherein the second portion of the first transmission line is positioned to allow coupling simultaneously to a third portion of the first transmission line.

4. The broadband balun structure as claimed in claim 1, wherein the transmission lines comprise one of stripline or microstrip.

5. The broadband balun structure as claimed in claim 4, wherein the coupling comprises broadside coupling of parallel line portions.

6. The broadband balun structure as claimed in claim 4, wherein the coupling comprises parallel-plate coupling of at least partially overlapped line portions on different layers.

7. The broadband balun structure as claimed in claim 4, wherein coupled portions of the first and second transmission lines are narrower than uncoupled portions of the first and second transmission lines.

8. The broadband balun structure as claimed in claim 4, wherein coupled portions of the first and second transmission lines positioned to couple simultaneously to two other line portions are narrower than portions coupled to only one other line portion.

9. A broadband balun structure, comprising:
a 180° hybrid using coupled-line structures; and
a phase-shift network using coupled-line structures, the coupled-line structures positioned to couple at least one line section simultaneously to two other line sections.

10. The broadband balun structure as claimed in claim 9, wherein the at least one line section simultaneously coupled to two other line sections is part of the 180° hybrid and the phase-shift network.

11. The broadband balun structure as claimed in claim 9, wherein the coupled-line structures are positioned to couple at least a second line section simultaneously to two other line sections.

12. The broadband balun structure as claimed in claim 9, wherein the coupled-line structures comprise one of stripline or microstrip.

13. The broadband balun structure as claimed in claim 12, wherein the coupled-line structures comprise parallel lines coupled by broadside coupling of the parallel lines.

14. The broadband balun structure as claimed in claim 12, wherein the coupled-line structures comprise lines on different layers of a substrate coupled by parallel-plate coupling of at least partially overlapped lines on different layers.

15. The broadband balun structure as claimed in claim 12, wherein line sections coupled to other line sections are narrower than uncoupled line sections.

16. The broadband balun structure claimed in claim 12, wherein line sections coupled simultaneously to the two other line sections are narrower than sections coupled to only one other line section.

17. A test and measurement system, comprising:
a test and measurement instrument; and
at least one balun structure comprising:
a single-ended port;
a balanced port having first and second sides;
a first transmission line connected between the single-ended port and the first side of the balanced port; and
a second transmission line connected to the second side of the balanced port,
the first transmission positioned to couple a first portion of the first transmission line simultaneously to both the second portion of the first transmission line and a portion of the second transmission line.

18. The test and measurement system as claimed in claim 17, further comprising a probe connected to the test and measurement instrument by a cable, wherein the at least one balun structure comprises one balun structure having the balanced port connected to the probe and the single-ended port connected to the cable.

19. The test and measurement system as claimed in claim 17, the test and measurement instrument further comprising an input amplifier, and the at least one balun structure comprises one balun structure having the singled-ended port connected to an input connector and a balanced port connected to the input amplifier.
